(19) United States
(12) Patent Application Publication
(10) Pub. No.: US 2025/0239473 A1
(43) Pub. Date: Jul. 24, 2025

(54) PROCESS CONDITION MEASUREMENT DEVICE INCLUDING THERMALLY ISOLATED ELECTRONIC MODULES

(71) Applicant: KLA Corporation, Milpitas, CA (US)

(72) Inventors: Farhat A. Quli, Castro Valley, CA (US); Razieh Mahzoon, Fremont, CA (US)

(21) Appl. No.: 18/967,329

(22) Filed: Dec. 3, 2024

Related U.S. Application Data
(60) Provisional application No. 63/622,140, filed on Jan. 18, 2024.

(51) Int. Cl. H01L 21/67; H01L 23/00; H01L 23/15; H01L 23/29; H01L 23/31; H01L 25/065

(52) U.S. Cl. CPC H01L 21/67253; H01L 23/15; H01L 23/29; H01L 23/3121; H01L 25/0655; H01L 24/48; H01L 2224/48225; H01L 2224/48245; H01L 2924/16195; H01L 2924/3512

(57) ABSTRACT

An instrumented wafer assembly for process condition monitoring is disclosed. The instrumented wafer assembly includes a cover wafer including one or more module openings and a substrate wafer. The cover wafer is contacted to the substrate wafer. The instrumented wafer assembly includes sensors embedded between the cover wafer and the substrate wafer. The one or more electronic modules are elevated above the substrate wafer with one or more module contacts to provide a thermal gap between the substrate wafer and the one or more electronic modules. The one or more electronic modules are aligned within the one or more module openings in the cover wafer. The instrumented wafer assembly includes one or more module lids to shield the one or more electronic modules, The one or more module lids are secured above the one or more module openings of the cover wafer with the module contacts.

### CROSS-REFERENCE TO RELATED APPLICATIONS

The present application claims the benefit under 35 U.S.C. § 119(e) of U.S. Provisional Application Ser. No. 63/622,140, filed Jan. 18, 2024, which is incorporated herein by reference in the entirety.

### TECHNICAL FIELD

The present disclosure generally relates to process condition substrate devices, and, more particularly, to an instrumented wafer assembly including thermally isolated electronic modules.

### BACKGROUND

As the demand for improved process monitoring systems continues to increase, the tolerances on process conditions in semiconductor device processing environments continue to decrease. Thermal uniformity within a processing system is one such condition. If the electronics of a process monitoring system are exposed to a temperature that exceeds a certain temperature some electronics may become permanently damaged and non-functional. Further, if a device is secured mechanically to a substrate, the materials used within the device may expand at different rates due to temperature differences and/or different thermo-mechanical properties. The expansion rates may cause undue stress at certain points of connection between the device and substrate, further causing damage and leading to non-functional devices if unmitigated.

It would be desirable to provide a solution that remedies the shortfalls of the previous approaches identified above.

### SUMMARY

An instrumented wafer assembly for process condition monitoring is disclosed, in accordance with one or more embodiments of the present disclosure. In embodiments, the instrumented wafer includes a cover wafer including one or more module openings. In embodiments, the instrumented wafer assembly includes a substrate wafer, wherein the cover wafer is contacted to the substrate wafer. In embodiments, the instrumented wafer assembly includes one or more sensors embedded between the cover wafer and the substrate wafer. In embodiments, the instrumented wafer assembly includes one or more electronic modules secured on one or more module bases with a plurality of module contacts such that the one or more electronic modules are elevated above the substrate wafer. In embodiments, the one or more electronic modules are aligned within the one or more module openings in the cover wafer. In embodiments, the instrumented wafer assembly includes one or more module lids to shield the one or more electronic modules. In embodiments, a respective module lid covers a respective module opening in the cover wafer and shields a respective electronic module, wherein the one or more module lids are secured above the one or more module openings of the cover wafer with the plurality of module contacts.

A method monitoring process conditions with an instrumented wafer assembly is disclosed, in accordance with one or more embodiments of the present disclosure. In embodiments, the method includes providing an instrumented wafer assembly including a cover wafer, a substrate wafer, and one or more electronic modules elevated above a surface of the substrate wafer; securing one or more module lids above an electronic module of the instrumented wafer assembly to shield the one or more electronic modules, wherein the one or more module lids are offset from a top surface of the cover wafer by a plurality of module contacts; acquiring a set of measurement parameters with one or more sensors embedded between the cover wafer and the substrate wafer of the instrumented wafer assembly and communicatively coupled to the one or more electronic modules; storing the set of measurement parameters within a memory of the one or more electronic modules; and transmitting a signal indicative of the set of measurement parameters to a remote data system.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF THE DRAWINGS

The numerous advantages of the disclosure may be better understood by those skilled in the art by reference to the accompanying figures.

FIG. 1A illustrates an assembled perspective view of an instrumented wafer assembly for process condition measurement, in accordance with one or more embodiments of the present disclosure.

FIG. 1B illustrates an exploded perspective view of the instrumented wafer assembly, in accordance with one or more embodiments of the present disclosure.

FIG. 1C illustrates a perspective view of an electronic module of the instrumented wafer assembly, in accordance with one or more embodiments of the present disclosure.

FIG. 1D illustrates a cross-sectional view of a module lid of the instrumented wafer assembly, in accordance with one or more embodiments of the present disclosure.

FIG. 2A illustrates a simplified cross-sectional view of a sensor located within a closed cavity of the instrumented wafer assembly, in accordance with one or more embodiments of the present disclosure.

FIG. 2B illustrates a simplified cross-sectional view of a sensor located within a closed cavity of the instrumented wafer assembly, in accordance with one or more embodiments of the present disclosure.

FIG. 3A illustrates a simplified cross-sectional view of an insulating layer of the instrumented wafer assembly disposed between a substrate wafer and a set of sensors, in accordance with one or more embodiments of the present disclosure.

FIG. 3B illustrates a simplified cross-sectional view of an insulating layer of the instrumented wafer assembly disposed between a cover wafer and a set of sensors, in accordance with one or more embodiments of the present disclosure.

FIG. 4 illustrates a top view of the instrumented wafer assembly depicting an insulating layer disposed beneath wire bonding of a sensor, in accordance with one or more embodiments of the present disclosure.

FIG. 5 illustrates a top view of the instrumented wafer assembly depicting an encapsulation of a sensor including spacer layer, in accordance with one or more embodiments of the present disclosure.

FIG. 6 illustrates a block diagram view of a process condition monitoring system incorporating the instrumented wafer assembly, in accordance with one or more embodiments of the present disclosure.

FIG. 7 illustrates a flowchart depicting a method of measuring process conditions within a processing environment using an instrumented wafer assembly, in accordance with one or more embodiments of the present disclosure.

### DETAILED DESCRIPTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

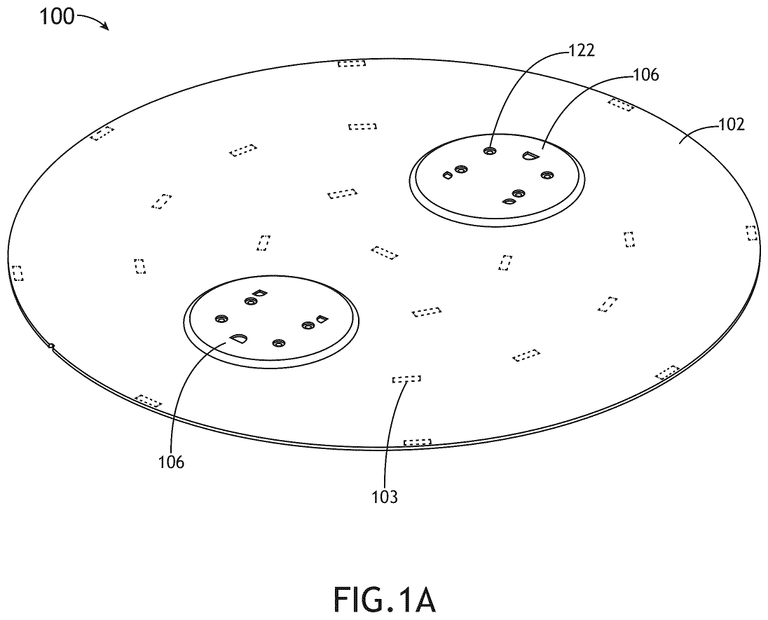

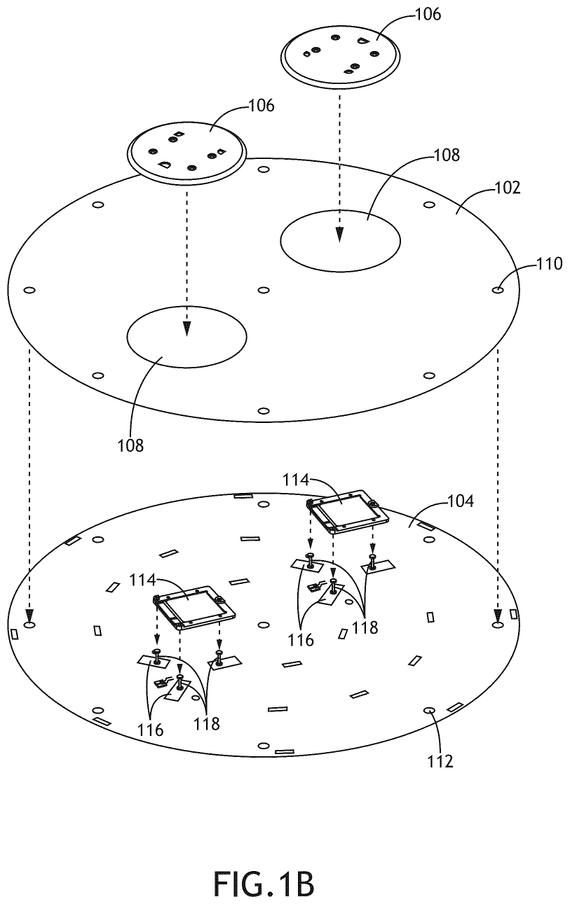

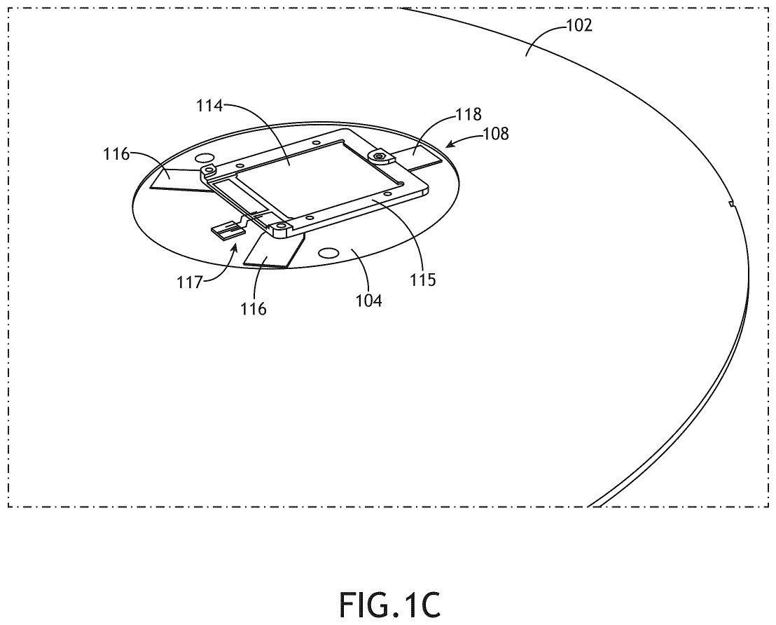

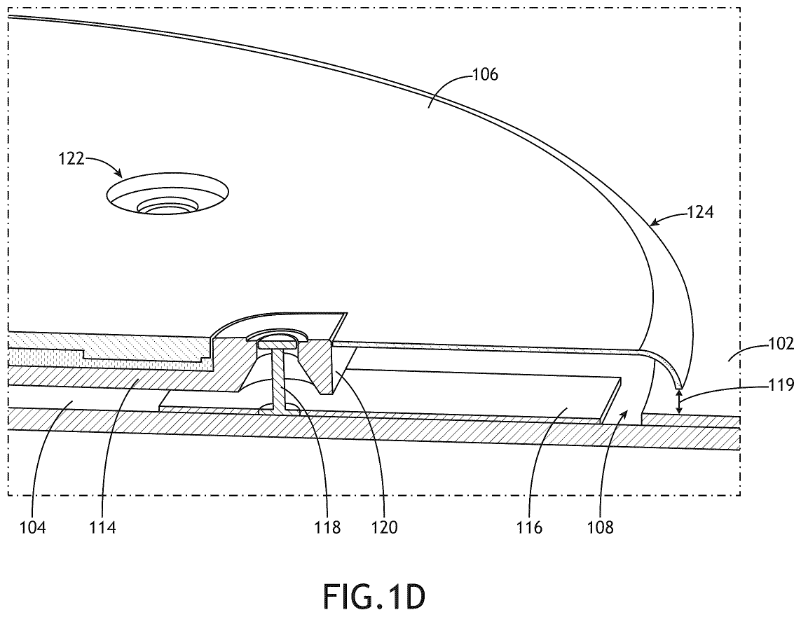

Referring generally to FIGS. 1-7, a process condition sensing device and method is described, in accordance with one or more embodiments of the present disclosure.

Embodiments of the present disclosure are directed to a process condition measurement device including an instrumented wafer assembly that operates in extremely high and/or low temperatures and in plasma conditions. Embodiments of the present disclosure are directed to an instrumented wafer assembly suitable for operation on a process chuck higher than 65° C. and/or lower than −10° C. in a variety of plasma conditions including, but not limited to, direct capacitive coupling, inductive coupling, and downstream plasmas. Embodiments of the present disclosure are directed to the elevation of electronic modules above the surface of the substrate wafer of an instrumented wafer assembly to reduce thermal conduction from the substate wafer to the electronics of the electronic modules. Additional embodiments of the present disclosure are directed to the elevation of module lids, which cover the electronic modules, above the surface of the cover wafer of the instrumented wafer assembly.

Process condition measurement devices are generally described in U.S. Pat. No. 8,033,190, issued on Oct. 11, 2011 to Renken et al.; U.S. Pat. No. 8,604,361, issued on Dec. 10, 2013 to Sun et al.; U.S. Pat. No. 9,719,867, issued on Aug. 1, 2017 to Sharratt et al.; U.S. Pat. No. 9,823,121, issued on Nov. 21, 2017 to Sun et al.; U.S. Pat. No. 10,460,966, issued on Oct. 29, 2019 to Sun et al.; U.S. Patent Publication No. 2017/0219437, published on Aug. 3, 2017; and U.S. Patent Publication No. 2019/0368944, published on Dec. 5, 2019, which are each incorporated herein by reference in their entirety.

FIGS. 1A-1B illustrate instrumented wafer assembly 100, in accordance with one or more embodiments of the present disclosure. FIG. 1A illustrates an assembled view of the instrumented wafer assembly 100 and FIG. 1B illustrates an exploded view of the instrumented wafer assembly 100. In embodiments, the instrumented wafer assembly 100 includes a cover wafer 102. The cover wafer 102 may include including one or more module openings 108. In embodiments, the instrumented wafer assembly 100 includes a substrate wafer 104. The cover wafer 102 may be secured to the substrate wafer 104. In embodiments, one or more sensors 103 are embedded between the cover wafer and the substrate wafer and are electrically connected to one or more electronic modules 114 such that data collected from the one or more sensors is transmitted to the one or more electronic modules 114. In embodiments, the one or more electronic modules 114 are disposed on one or more module bases and elevated above the surface of substrate wafer 104, via module contacts 118. In addition, the one or more electronic modules 114 are aligned within the one or more module openings 108 in the cover wafer 102. In embodiments, the instrumented wafer assembly 100 includes one or more module lids 106 to shield the one or more electronic modules 114. In this regard, a respective module lid 106 covers a respective module opening 108 in the cover wafer 102 and shields a respective electronic module 114. In embodiments, the one or more module lids 106 are secured above the one or more module openings 108 of the cover wafer 102 with the one or more module contacts 118 connected to the substrate wafer 104.

The one or more sensors 103 may be distributed between the cover wafer 102 and substrate wafer 104 and configured to measure the uniformity of one or more measurement parameters across the instrumented wafer assembly 100. The one or more sensors 103 may include any sensor type known in the art. For example, one or more sensors 103 may include, but are not limited to, temperature sensors, optical detectors, pressure sensors, chemical sensors, and the like. In embodiments, the one or more sensors 103 are connected to one or more electronic modules 114 via an array of electrical connections (e.g., thin film interconnects and/or discrete interconnects). In embodiments, the one or more sensors 103 may be wire-bonded discrete sensors. In embodiments, the one or more sensors 103 may be solid state devices fabricated directly on the surface of the substrate wafer 104.

The instrumented wafer assembly 100 may be constructed by the lamination of the cover wafer 102 and the substrate wafer 104. For example, the instrumented wafer assembly 100 may be formed by the lamination of two silicon wafers. The cover wafer 102 and the substrate wafer 104 may be formed from any suitable materials known in the art. In embodiments, the cover wafer 102 and/or substrate wafer 104 may be formed from a metal, a semiconductor material, a ceramic, or a crystalline material. For example, the cover wafer 102 and/or the substrate wafer 104 may be formed from, but are not limited to, silicon, aluminum, silicon nitride, or quartz. The cover wafer 102 and the substrate wafer 104 may take on any size (e.g., 300 mm).

In embodiments, the cover wafer 102 and the substrate wafer 104 are both conductive. The cover wafer 102 may be electrically contacted to the substrate wafer 104 via at least one of conductive contacts or a conductive adhesive. For example, the cover wafer 102 and the substrate wafer 104 may be electrically connected via corresponding electrical contacts 110, 112 located on the cover wafer 102 and the substrate wafer 104 respectively. It is noted that the electrical contact between the cover wafer 102 and the substrate wafer 104 with electrically conductive contacts provides for plasma shielding. The electrical contacts 110, 112 may include, but are not limited to, silver, platinum, TiN, indium, or aluminum.

In embodiments, as shown in FIG. 1C, the one or more electronic modules 114 are offset from the surface of substrate wafer 104 via the module contacts 118 connected to module bases 116. In this regard, electronic components may be mounted on the elevated electronic modules 114 to reduce thermal conduction between the substrate wafer 104 and the one or more electronic modules 114. In this regard, the elevated electronic modules 114 provide a thermal gap between the substrate wafer 104 and the elevated electronic modules 114 so that the electronics and other sensitive components are temporarily kept at a different temperature than the substrate wafer 104. The one or more electronic modules 114 may be pre-heated or pre-cooled to provide additional time in a cooled or heated environment respectively. In additional embodiments, to prevent the modules from plasma arcing the module components may be designed with rounded edges. In embodiments, the one or more module lids 106 may include one or more access points 122. For example, the one or more access points 122 may include, but are not limited to, one or more vents.

In embodiments, the one or more module bases 116 (e.g., three module bases) may include one or more module feet. For instance, the one or more module feet may be connected to the substrate wafer 104 (e.g., connected via wire-bonding) and a given electronic module 114 may be secured on the one or more module feet (e.g., three module feet) via module contacts 118. For example, each of the module contacts 118 may be connected to a module foot of the module feet. The electronic module 114 may be wire-bonded 117 to the substrate wafer 104 and/or the cover wafer 102.

FIG. 1D illustrates a cross-section view of a single module lid 106 secured over an opening 108 in the cover wafer 102, in accordance with one or more embodiments of the present disclosure. In embodiments, module lid 106 is offset from the top surface of the cover wafer 102. For example, as shown in FIG. 1B and 1D, the one or more module lids 106 may be offset from the cover wafer 102 by the set of module contacts 118 to create a gap 119 between the one or more module lids 106 and the cover wafer 102. By way of another example, the one or more module lids 106 may be offset from the cover wafer 102 by the one or more electronic modules 114 themselves. It is noted that the gap 119 between the one or more module lids 106 and the cover wafer 102 is minimized to block RF transmission to mitigate measurement noise. The gap 119 also provides temporary thermal insulation between module lid 106 and cover wafer 102. The size of the gap 119 may be selected such that it is smaller than the wavelength of RF radiation present in the measurement environment. For example, the gap 119 may be, but is not required to be, less than 3 mm.

The module contacts 118 may be formed from any suitable material. For example, the module contacts 118 may be formed from metal. For example, the module contacts 118 may include, but are not limited to, metal pegs. In embodiments, as shown in FIG. 1D, a respective module contact 118 is contacted to a respective module base 116 and secured to the electronic module 114 via a respective contact interlock 120. The cover wafer 102 may be secured to the electronic module 114 via interlocking recesses/protrusions in the electronic module 114 and the cover wafer 102. In this regard, the module contacts 118, such as metal pegs, serve to secure the one or more electronic modules 114 above the substrate wafer 104 and the one or more module lids 106 over the one or more openings 108 of the cover wafer 102, while also electrically contacting the cover wafer 102 to the substrate wafer 104 (via the module feet). In embodiments, the one or more module lids 106 may be constructed to have curved edges 124. The utilization of module lids with curved edges reduces the likelihood of plasma arcing at the module lids.

The one or more module lids 106 may be formed form any suitable materials known in the art. In embodiments, the one or more module lids 106 may be formed from a metal, an alloy, a semiconductor material, a ceramic, or a crystalline material. For example, the one or more module lids 106 may be formed from, but are not limited to, nickel, Kovar, Invar, silicon, stainless steel, or aluminum.

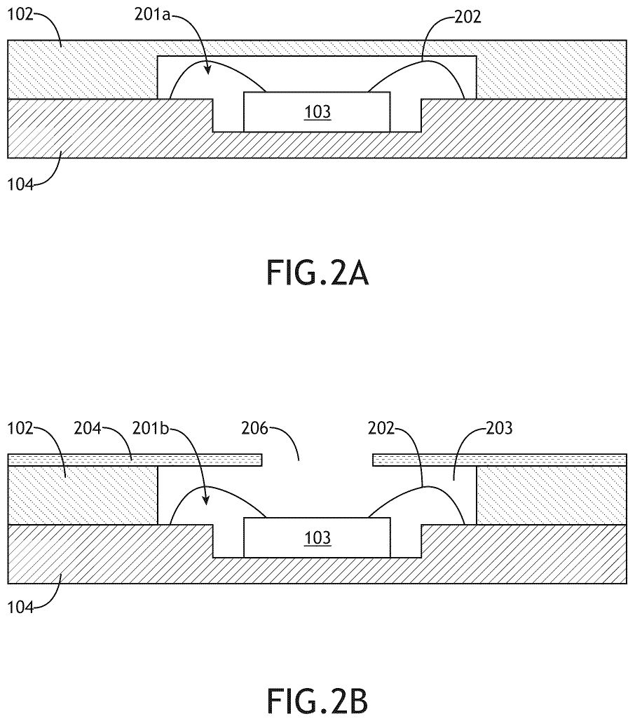

FIGS. 2A-2B illustrate simplified side-views of the instrumented wafer assembly 100 depicting a sensor 103 embedded within the instrumented wafer assembly 100, in accordance with one or more embodiments of the present disclosure. In embodiments, as shown in FIG. 2A, the one or more sensors 103 may be housed in closed cavities 201a formed between the cover wafer 102 and the substrate wafer 104. In this regard, the closed cavity 201a is closed from the environment surrounding the instrumented wafer assembly 100. The closed cavity 201a may be formed by removing a bottom portion of the cover wafer 102 and/or a top portion of the substrate wafer 104.

In alternative and/or additional embodiments, as shown in FIG. 2B, the one or more sensors 103 may be housed in open cavities 201b. In this embodiment, for one or more sensors 103, the cover wafer 102 includes one or more through-holes 203 such that a given through-hole 203 is aligned with a given sensor 103. Additionally, the instrumented wafer assembly 100 may include an aperture plate 204 including one or more apertures 206. The aperture plate 204 may be constructed such that the apertures 206 of the aperture plate 204 align with the through-holes 203 of the cover wafer 102 and the sensors 103. The aperture plate 204 may be formed from any suitable material including, but not limited to, nickel, Kovar, Invar, silicon, stainless steel, aluminum, and the like. It is noted that the through-hole design of FIG. 2B may reduce the risk of the cover wafer 102 breaking during the lamination step due to the thermal expansion of the wafer 102. The through-hole design mitigates shorting/arcing of the sensor wire bonds 202 and other electrical components within the open cavity 201b to the cover wafer 102, while the aperture plate 204 maintains adequate protection of the sensor 103 and provides free gas flow from the testing environment to the sensor. It is noted that the examples of FIGS. 2A-2B depict a single sensor 103 and sensor cavity. It is noted that multiple sensors 103, as shown in FIG. 1A, may be housed in open and/or closed cavities according to the embodiments of FIGS. 2A-2B. For example, some of the sensors 103 may be housed in closed cavities 201a, while some of the sensors 103 are housed in open cavities 201b.

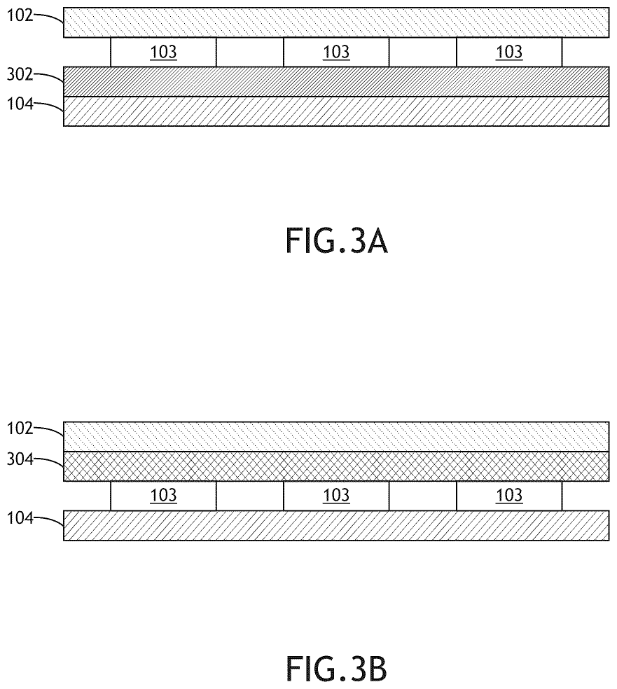

FIGS. 3A-3B illustrate simplified side-views of the instrumented wafer assembly 100 depicting the implementation of one or more insulation layers 502, 504, in accordance with one or more embodiments of the present disclosure. In embodiments, as shown in FIG. 3A, one or more insulation layers 302 may be disposed between the substrate wafer 104 and the one or more sensors 103. For example, the one or more insulation layers 302 may include, but are not limited to, silicon dioxide, silicon nitride, mica, epoxy, borosilicate, silicon, quartz, and/or a thick film dielectric. In alternative and/or additional embodiments, as shown in FIG. 3B, one or more insulation layers 304 may be disposed between the cover wafer 102 and the one or more sensors 103. For example, the one or more insulation layers 304 may include, but are not limited to, silicon dioxide, silicon nitride, mica, epoxy, borosilicate, silicon, quartz, and/or a thick film dielectric. It is noted that insulation layers 302 and 304 may be used in combination to insulate between the one or more sensors 103 and the cover wafer 102 and the substrate wafer 104.

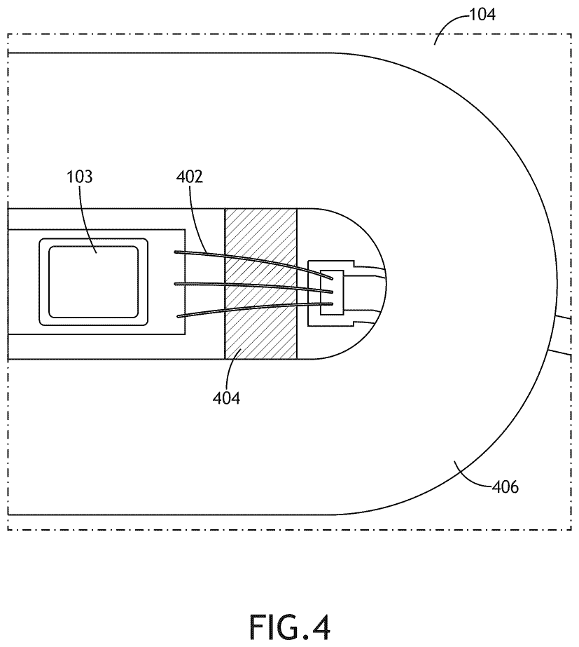

FIG. 4 illustrates a top view of the instrumented wafer assembly 100 depicting insulation of wire bonding 402, in accordance with one or more embodiments of the present disclosure. In embodiments, an insulation layer 404 may be disposed beneath wire bonding 402 of the sensor 103 to prevent the wires from electrically connecting to the substrate wafer 104.

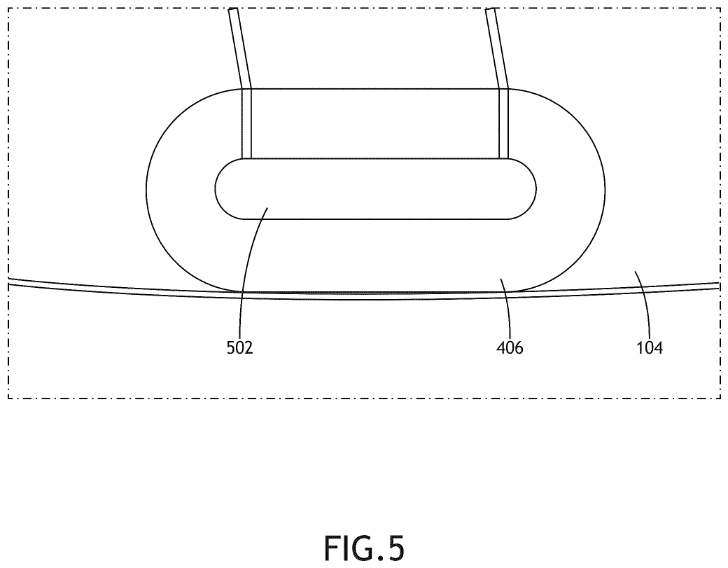

FIG. 5 illustrates a top view of the instrumented wafer assembly 100 depicting the encapsulation of the one or more sensors 103, in accordance with one or more embodiments of the present disclosure. In embodiments, the one or more sensors 103 are encapsulated with insulating material to create electrical insulation between the one or more sensors 103 and the cover wafer 102. The encapsulation material may include any suitable insulating material including, but not limited to, encapsulation material might be epoxy, fused silica powder, AlN powder, aluminum oxide powder, polyimide base epoxy, and the like. In embodiments, a spacer layer 406 may be used to assist with the leveling of the encapsulation height, allowing for a controlled encapsulation height before lamination. The control of the encapsulation height may prevent cover wafer cracking during lamination. The spacer layer 406 may be formed from any suitable material including, but not limited to, aluminum oxide, aluminum nitride, polyimide layer, epoxy layer, mica.

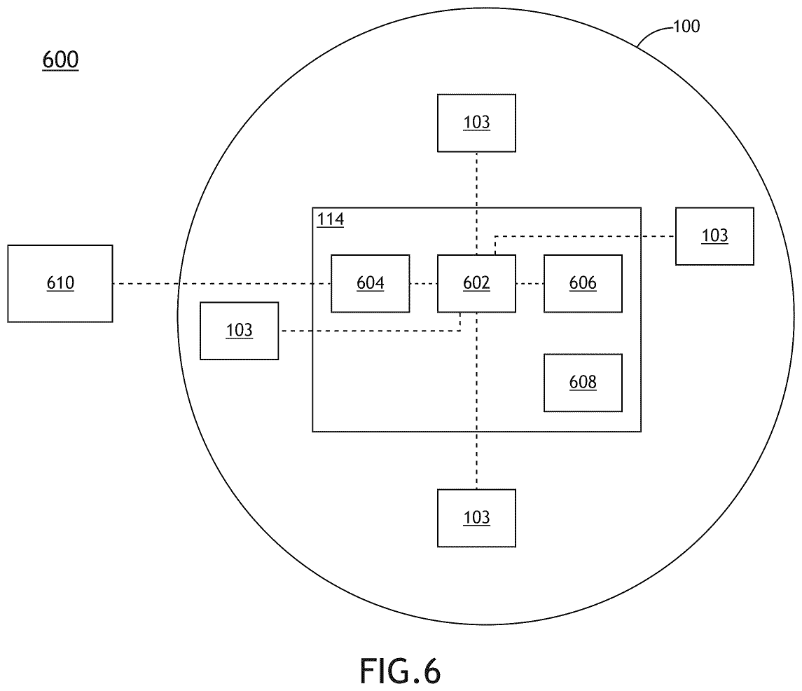

FIG. 6 illustrates a simplified block diagram of a measurement system 600 incorporating the instrumented wafer assembly 100, in accordance with one or more embodiments of the present disclosure. In embodiments, each electronic module 114 includes one or more processors 602, communication circuitry 604, memory 606, and a power source 608.

The one or more processors 602 may be configured to receive one or more measurement parameters from the one or more sensors 103 of the instrumented wafer assembly 100. The memory 606 may store program instructions for the one or more processors 602 and/or the measurement parameters received from the one or more sensors 103 for later retrieval. The communication circuitry 604 may be configured to transmit one or more signals to an off-wafer location. In embodiments, the communication circuitry 604 (e.g. RF communication circuitry, IR communication circuitry, and the like) is coupled to a remote data system 610. In embodiments, the instrumented wafer assembly and/or the remote data system may be automatically handled or controlled by a facility automation system.

The one or more processors 602 may include any processor or processing element known in the art. For the purposes of the present disclosure, the term “processor” or “processing element” may be broadly defined to encompass any device having one or more processing or logic elements. In this sense, the one or more processors 602 may include any device configured to execute algorithms and/or instructions (e.g., program instructions stored in memory). It should be recognized that the steps described throughout the present disclosure may be carried out by a single processor or, alternatively, multiple processors. The memory 606 may include any data storage medium known in the art suitable for storing program instructions executable by the associated one or more processors 602 and/or measurement data. For example, the memory 606 may include a non-transitory memory medium. By way of another example, the memory 606 may include, but is not limited to, a read-only memory (ROM), a random-access memory (RAM), a solid-state memory, and the like.

The electronic module 114 may include any type of power source known in the art. For example, the electronic module 114 may include one or more batteries.

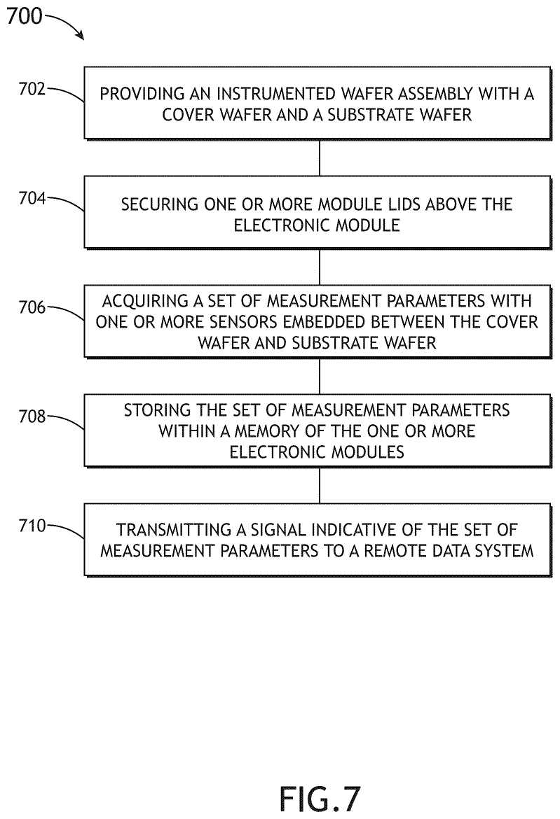

FIG. 7 illustrates a flowchart depicting method 700 of operating an instrumented wafer assembly to measure process conditions within a selected processing environment, in accordance with one or more embodiments of the present disclosure. It is noted herein that the steps of method 700 may be implemented all or in part by instrumented wafer assembly 100. It is further recognized, however, that method 700 is not limited to the instrumented wafer assembly 100 in that additional or alternative device-level embodiments may carry out all or part of the steps of method 700.

In step 702, an instrumented wafer assembly is provided. For example, an instrumented wafer assembly 100 including a cover wafer 102 and a substrate wafer 104 is provided. The substrate wafer 104 may include one or more electronic modules 114 elevated above the surface of the substrate wafer 104 via one or more module contacts 118 and electrically connected to the substrate wafer 104 via the one or more module bases 116. The cover wafer 102 may include one or more module openings 108 corresponding to the position of the one or more electronic modules 114.

In step 704, one or more module lids are secured above the one or more electronic modules to shield the one or more electronic modules. In embodiments, the one or more module lids are offset from a top surface of the cover wafer by module contacts to reduce RF interference and thermally insulate the one or more electronic modules. In embodiments, the one or more electronic modules may be pre-heated or pre-cooled to establish a desired thermal state of one or more electronic modules 114. It is noted that step 702 and 704 may be performed in separate steps or a single combined step.

In step 706, one or more sensors embedded between the cover wafer and the substrate wafer 104 may acquire a set of measurement parameters. For example, sensors 103 distributed across the substrate wafer 104 may acquire measurement parameters (e.g., temperature, pressure, radiation level, chemical concentration, etc.) as function of position across the substrate wafer 104. The measurement parameter data from the sensors 103 may be transmitted to one or more processors of the one or more electronic modules 114.

In step 708, the set of measurement parameters may be stored with a memory of the one or more electronic modules.

In step 710, a signal indicative of the set of measurement parameters may be transmitted to a remote data system. For example, the one or more electronic modules 114 may include communication circuitry (e.g., transmitter, receiver, transceiver) for transmitting a signal indicative of the measurement parameter data to a remote data system 130. The communication circuitry may be configured to transmit any signal in the art suitable for data transmission including, but not limited to, an RF signal, an IR signal, or an optical signal.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein

One skilled in the art will recognize that the herein described components, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, devices, and objects should not be taken as limiting.

The previous description is presented to enable one of ordinary skill in the art to make and use the disclosure as provided in the context of a particular application and its requirements. As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments. Therefore, the present disclosure is not intended to be limited to the particular embodiments shown and described, but is to be accorded the widest scope consistent with the principles and novel features herein disclosed.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An instrumented wafer assembly comprising:
a cover wafer including one or more module openings;
a substrate wafer, wherein the cover wafer is contacted to the substrate wafer;
one or more sensors embedded between the cover wafer and the substrate wafer;
one or more electronic modules secured on one or more module bases with a plurality of module contacts, wherein the one or more electronic modules are elevated above the substrate wafer with the plurality of module contacts, wherein the one or more electronic modules are aligned within the one or more module openings in the cover wafer; and
one or more module lids to shield the one or more electronic modules, wherein a respective module lid covers a respective module opening in the cover wafer and shields a respective electronic module, wherein the one or more module lids are secured above the one or more module openings of the cover wafer with the plurality of module contacts.

2. The instrumented wafer assembly of claim 1, wherein the one or more sensors are connected to the one or more electronic modules via electrical connections.

3. The instrumented wafer assembly of claim 1, wherein the one or more module lids are offset from a top surface of the cover wafer by at least one of the module or the plurality of module contacts to a create a gap between the one or more module lids and the cover wafer.

4. The instrumented wafer assembly of claim 3, wherein the plurality of module contacts comprises a plurality of metal contacts.

5. The instrumented wafer assembly of claim 3, wherein at least some of the one or more module bases comprise a plurality of module feet, wherein the module feet are electrically contacted to the substrate wafer.

6. The instrumented wafer assembly of claim 5, wherein each of the plurality of module contacts is connected to a module foot of the plurality of module feet.

7. The instrumented wafer assembly of claim 1, wherein the one or more module lids have curved edges.

8. The instrumented wafer assembly of claim 1, wherein the one or more module lids are formed from at least one of nickel, kovar, invar, silicon, stainless steel, or aluminum.

9. The instrumented wafer assembly of claim 1, wherein the cover wafer includes one or more apertures.

10. The instrumented wafer assembly of claim 1, wherein the cover wafer is closed.

11. The instrumented wafer assembly of claim 1, wherein the cover wafer and the substrate wafer are conductive.

12. The instrumented wafer assembly of claim 11, wherein the cover wafer is electrically contacted to the substrate wafer via at least one of conductive contacts or a conductive adhesive.

13. The instrumented wafer assembly of claim 1, wherein at least one of the cover wafer or the substrate wafer comprise at least one of silicon, aluminum, silicon nitride, or quartz.

14. The instrumented wafer assembly of claim 1, wherein the one or more sensors are encapsulated in an insulating material to prevent electrical contact between the one or more sensors, electrical connections, and the cover wafer.

15. The instrumented wafer assembly of claim 14, further comprising a spacer layer, wherein the spacer layer is configured to level the insulating material of the encapsulated one or more sensors.

16. The instrumented wafer assembly of claim 1, further comprising one or more insulation layers disposed between at least one of the one or more sensors and one or more electrical connections and the substrate wafer to prevent electrical contact between at least one of the one or more sensors or the one or more electrical connections and the substrate wafer.

17. The instrumented wafer assembly of claim 1, further comprising an insulating layer disposed between at least one of the one or more sensors and one or more electrical connections and the cover wafer to prevent electrical contact between at least one of the one or more sensors or the one or more electrical connections and the cover wafer.

18. A method comprising:
providing an instrumented wafer assembly including a cover wafer, a substrate wafer, and one or more electronic modules elevated above a surface of the substrate wafer;
securing one or more module lids above an electronic module of the instrumented wafer assembly to shield the one or more electronic modules, wherein the one or more module lids are offset from a top surface of the cover wafer by a plurality of module contacts;
acquiring a set of measurement parameters with one or more sensors embedded between the cover wafer and the substrate wafer of the instrumented wafer assembly and communicatively coupled to the one or more electronic modules;
storing the set of measurement parameters within a memory of the one or more electronic modules; and
transmitting a signal indicative of the set of measurement parameters to a remote data system.

19. The method of claim 18, further comprising establishing a thermal state of the one or more electronic modules of the instrumented wafer assembly.

20. The method of claim 19, wherein establishing a thermal state of the one or more electronic modules of the instrumented wafer assembly comprises:
cooling the one or more electronic modules of the instrumented wafer assembly.

21. The method of claim 19, wherein establishing a thermal state of the one or more electronic modules of the instrumented wafer assembly comprises:
heating the one or more electronic modules of the instrumented wafer assembly.

22. The method of claim 18, wherein at least one of the instrumented wafer assembly or the remote data system is automatically handled by a facility automation system.
